(19) United States
(12) Patent Application Publication
(10) Pub. No.: US 2023/0117125 A1
(43) Pub. Date: Apr. 20, 2023

(54) METHODS AND CONTROL SYSTEMS FOR CONTROLLING FLUID CONDITIONING SYSTEM INCLUDING PLURAL FLUID CONDITIONING UNITS

(71) Applicant: Munters Corporation, Daleville, VA (US)

(72) Inventors: Xindi Cai, Ballwin, MO (US); William Mauro Beard, Kennesaw, GA (US)

(21) Appl. No.: 18/082,774

(22) Filed: Dec. 16, 2022

(51) Int. Cl. F24F 11/54; F24F 11/63; H05K 7/20

(52) U.S. Cl. CPC F24F 11/54; F24F 11/63; H05K 7/2079

(57) ABSTRACT

In a controller for a fluid conditioning unit, a fluid conditioning system including a plurality of fluid conditioning units, and a method of conditioning a fluid, each fluid conditioning unit includes a unit controller configured to operate the fluid conditioning unit. One unit controller of the plurality of the unit controllers may function as a master control module and provide at least one operational set point to each of the unit controllers. The controller may include instructions stored therein that cause the controller (i) to operate as a unit controller controlling the fluid conditioning unit and (ii) to operate as a master controller. The method may include selecting a new unit controller to function as the master control module from the unit controllers of the plurality of fluid conditioning units when the previous unit controller operating as a master control module for the fluid conditioning system goes offline.

### FIELD OF THE INVENTION

The invention relates to fluid conditioning systems, particularly systems that include a plurality of fluid conditioning units. The invention also relates to methods and control systems for controlling the fluid conditioning systems.

### BACKGROUND OF THE INVENTION

To condition air for large commercial and industrial spaces, multiple air conditioning units may be used for a single space. The multiple air conditioning units work together to condition the air, such as cooling the air, within the space, and the multiple air conditioning units are collectively controlled to condition the space.

### SUMMARY OF THE INVENTION

In one aspect, the invention relates to a fluid conditioning system for conditioning a fluid. The fluid conditioning system includes a plurality of fluid conditioning units. Each unit of the plurality of fluid conditioning units is configured to condition a fluid. Each fluid conditioning unit of the plurality of fluid conditioning units includes a unit controller configured to operate the fluid conditioning unit. The unit controllers of the plurality of fluid conditioning units are communicatively coupled to each other. One unit controller of the plurality of the unit controllers functions as a master control module. The master control module provides at least one operational set point to each of the unit controllers.

In another aspect, the invention relates to a controller for a fluid conditioning unit. The controller comprises a processor and a computer-readable storage medium. The computer-readable storage medium stores instructions, which, when executed by the processor, cause the controller (i) to operate as a unit controller controlling the fluid conditioning unit based on at least one operational set point and (ii) to operate as a master controller. The controller is selectively operable as the master controller, and, when operating as the master controller, the instructions cause the controller to output the at least one operational set point.

In a further aspect, the invention relates to a method of conditioning a fluid using a fluid conditioning system. The fluid conditioning system includes a plurality of fluid conditioning units. Each fluid conditioning unit of the plurality of fluid conditioning units includes a unit controller configured to operate the fluid conditioning unit. The method includes determining when a unit controller operating as a master control module for the fluid conditioning system goes offline. The unit controller functioning as the master control module is communicatively coupled to each of the unit controllers to provide at least one operational set point to each of the unit controllers. The method further includes selecting a new unit controller to function as the master control module from the unit controllers of the plurality of fluid conditioning units.

These and other aspects of the invention will become apparent from the following disclosure.

### BRIEF DESCRIPTION OF THE DRAWINGS

FIG. 1 shows a data center with an air conditioning system according to a preferred embodiment of the invention.

FIG. 2 is a schematic diagram showing one of the air conditioning units of the air conditioning system shown in FIG. 1 fluidly connected to a server room of the data center.

FIG. 3 is a schematic diagram of a control system for the air conditioning system shown in FIG. 1.

FIG. 4 is a schematic diagram of the control system shown in FIG. 3 where a unit controller functioning as the master controller has failed and is offline.

FIG. 5 is another schematic diagram of the control system for the air conditioning system shown in FIG. 1.

FIG. 6 is a schematic diagram of the control system shown in FIG. 5 illustrating one of the air conditioning units having changed groups.

FIG. 7 is a further schematic diagram of the control system for the air conditioning system shown in FIG. 1.

FIG. 8 is a schematic diagram of the control system shown in FIG. 7 illustrating one of the air conditioning units having changed groups.

FIG. 9 is a schematic of a general-purpose computing device.

### DETAILED DESCRIPTION OF THE PREFERRED EMBODIMENTS

A plurality of air conditioning units may be operated in conjunction with each other to condition the air for a space. To operate these air conditioning units in conjunction with each other, a master controller may be used to control individual unit controllers of each of the air conditioning units. For critical air conditioning systems, such as cooling systems used for a data center, for example, a redundant master controller is needed in the event the master controller fails. A master controller that is separate from the individual unit controllers and its redundant back-up systems adds to the complexity of the control system for the air conditioning system. Having a master controller that is separate from the individual unit controllers may also provide challenges to integrate and have the master controller operate the individual unit controllers. In embodiments discussed herein, an air conditioning system includes a plurality of air conditioning units, each with a unit controller. All of the unit controllers may be operable also as a master controller in addition to a unit controller. More specifically, each unit controller includes a master control module that provides the control of a master controller and one of the unit controllers is functioning as the master control module at a given time. If the master control module (or unit controller functioning as the master control module) fails, the remaining unit controllers select another unit controller to function (operate) as the master control module, thereby providing redundancy for critical systems without the additional complexity of multiple separate master controllers.

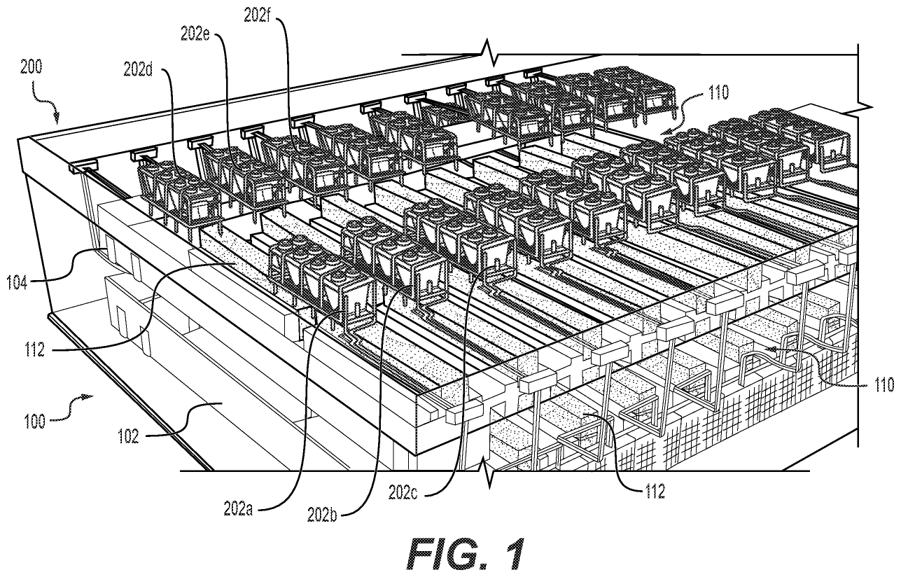

FIG. 1 shows a data center 100 with an air conditioning system 200 according to a preferred embodiment of the invention. Although the air conditioning system 200 is shown and described for use in a data center 100, the air conditioning system 200 is not limited to this application and may be used in other suitable air conditioning applications. In addition, the air conditioning system 200 shown in this embodiment is a cooling system that cools air to be supplied to the data center 100. However, embodiments discussed herein may be applicable and implemented on any fluid conditioning system of which the air conditioning system 200 is an example. Other suitable fluid conditioning systems include those that condition a liquid or air. Liquid conditioning system include, for example, liquid cooling systems or liquid heating and cooling systems. Other air conditioning systems include, for example, heating and cooling systems, dehumidification systems, and humidification systems.

The air conditioning system 200 includes a plurality of air conditioning units 202. As used herein, reference numeral 202 generically refers to an air conditioning unit, and where a specific air conditioning unit is being referred to, a reference character (such as a, b, c, d, e, or f) will be appended to reference numeral 202 (e.g., first air conditioning unit 202a). As noted above, the embodiments discussed herein are applicable to other fluid conditioning systems and such systems may include a plurality of fluid conditioning units. The air conditioning units 202 are examples of such fluid conditioning units and the discussion of the air conditioning units 202 may also apply to these fluid conditioning units.

Electronic components, such as servers, may be mounted on racks 112, and in a data center 100 these racks 112 may be arranged in rows forming aisles therebetween. The racks 112 may be located in one or more server rooms 110 of the data center 100. The data center 100 shown in FIG. 1 is a multi-story data center 100 including a plurality of floors. In this embodiment, the data center 100 has two floors (a first floor 102 and a second floor 104) with at least one server room 110 on each floor.

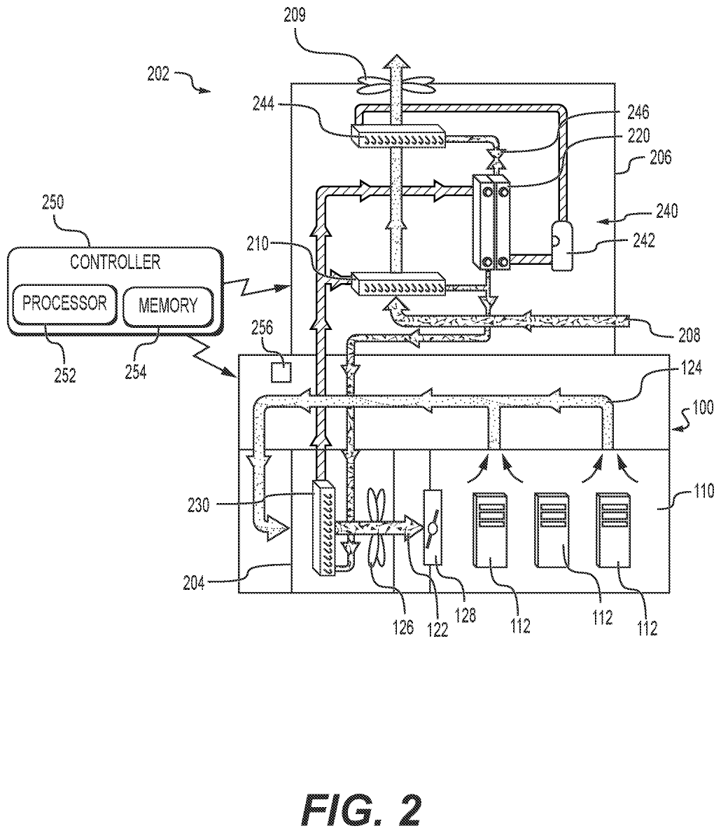

FIG. 2 is a schematic diagram showing one of the air conditioning units 202 fluidly connected to a server room 110 of the data center 100. The server room 110 is an example of a space to be conditioned by the air conditioning system 200. As noted above, the air conditioning system 200 is an air-cooling system, and thus the air conditioning unit 202 is an air-cooling unit fluidly connected to the server room 110 to cool the air in the server room 110. The air conditioning unit 202 schematically shown in FIG. 2 is the cooling system shown and described in U.S. Patent Application Pub. No. 2021/0368647, the disclosure of which is incorporated by reference herein in its entirety, but any suitable cooling system may be used.

Cool, supply air 122 from the cooling system is directed into the data center 100, and more specifically, into the server room 110. As the air passes through the racks 112, the air draws heat from the electronic components, cooling them and resulting in hot air. The hot air is then directed back to the air conditioning system 200 as hot, return air 124. Supply air fans 126 are used to draw the return air 124 from the server room 110, pass the return air 124 through the air conditioning unit 202, where it is cooled, and then return the now cooled return air 124 to the data center 100 as supply air 122. A supply air damper 128 may be used to control the flow of supply air 122 into the server room 110.

The air conditioning unit 202 may be divided into two sections, an interior air handler 204 and an exterior condensing unit 206. The portion of the air conditioning unit 202 through which the return air 124 flows, is cooled, and is returned as supply air 122 is referred to herein as the interior air handler 204. In this embodiment, at least one interior air handler 204 is positioned on one of the floors 102, 104, to cool the electronic components located in the racks 112 of the server room 110 on the corresponding floor 102, 104. Of course, other suitable arrangements of the air conditioning unit 202 may be used, such as where the entire air conditioning unit 202 is positioned outside the server room 110, as a packaged unit, for example, and air is ducted between the server room 110 and the air conditioning unit 202.

The air conditioning unit 202 of this embodiment has two modes, a passive mode and an active mode. The passive mode may also be referred to as an economization mode. The air conditioning unit 202 incorporates the ability to utilize ambient free cooling sinks (passive or economization mode) and to provide active cooling when available ambient free cooling sinks are not at a low enough temperature to provide sufficient heat rejection (active mode). This is accomplished by including two separate condensers 210, 220 operating in parallel. One condenser is referred to herein as a passive condenser 210 and is used in the passive (economization) mode. The other condenser is referred to herein as an active condenser 220 and is used in the active mode. The passive condenser 210 and the active condenser 220 are located in the exterior condensing unit 206.

The interior air handler 204 includes an evaporator 230 and the hot, return air 124 is directed over the evaporator 230 by the return air 124. The hot, return air 124 evaporates a primary cooling medium contained within the evaporator 230 as the return air 124 passes over the outer surface of the evaporator 230. The phase change of the primary cooling medium from a liquid phase to a gas (or vapor) phase cools the return air 124, allowing it to be returned to the data center 100 as cool, supply air 122. The evaporator 230 is fluidly coupled to each of the passive condenser 210 and the active condenser 220, depending upon mode, in which the primary cooling medium is cooled and condensed before flowing back to the evaporator 230. The passive condenser 210 of this embodiment is a coil, and scavenger air 208 is drawn across an outer surface of the passive condenser 210 by scavenger fans 209 to cool and condense the primary cooling medium. In this embodiment, the scavenger air 208 is ambient air drawn from the outdoor environment surrounding the air conditioning unit 202 and, more specifically, the condensing unit 206.

When the ambient air conditions are not sufficient to cool the return air 124 to the desired conditions (e.g., temperature) for the supply air 122, the air conditioning unit 202 may be operated in an active mode and the primary cooling medium is condensed by the active condenser 220. In the active condenser 220, heat is transferred from the primary cooling medium to the secondary cooling medium of a secondary cooling system 240. The secondary cooling medium may be any suitable refrigerant medium, including, for example, cooled (or chilled) water or a vapor change refrigerant used in a direct expansion cooling system. In this embodiment, the secondary cooling system 240 is a direct expansion (DX) cooling system using the common refrigeration cycle, and the secondary cooling medium is any suitable refrigerant used in such systems. The secondary cooling system 240 includes a compressor 242 to increase the pressure and temperature of the secondary cooling medium before it is cooled in a condenser 244. In this embodiment, the condenser 244 of the secondary cooling system 240 may also be cooled by the scavenger air. The secondary cooling medium then passes through an expansion valve 246, reducing its pressure and temperature, before flowing into the active condenser 220.

Each air conditioning unit 202 includes a unit controller 250 configured to operate the air conditioning unit 202. In particular, the unit controller 250 is communicatively coupled to sensors within the air conditioning unit 202 to receive data about the operation of the air conditioning unit 202. The unit controller 250 is also operatively coupled to the various components of the air conditioning unit 202 to operate the air conditioning unit 202 to provide supply air 122 at the desired operating conditions. For example, the unit controller 250 may be operatively coupled to the supply air fans 126, the supply air damper 128, the scavenger fans 209, the compressor 242, the condenser 244, and the like. Such components are examples of adjustable components of the air conditioning unit 202. The unit controller 250 is thus operatively coupled to at least one adjustable component to adjust the operation of the adjustable component, and the adjustable component may be, for example, one of a fan, a compressor, a pump, a valve, a damper, and an electric heater. Such components may be adjustable by the use of a drive mechanism, such as a motor, including a variable speed motor, and an actuator, and, more specifically, the unit controller 250 may be operatively coupled to the drive mechanism to operate or adjust the drive mechanism to adjust the operation of the adjustable component. Alternatively or additionally, such components may be adjustable by the use of a switch or relay. As will be described further below, the unit controller 250 is configured to adjust the operation of the at least one adjustable component based on at least one operational set point.

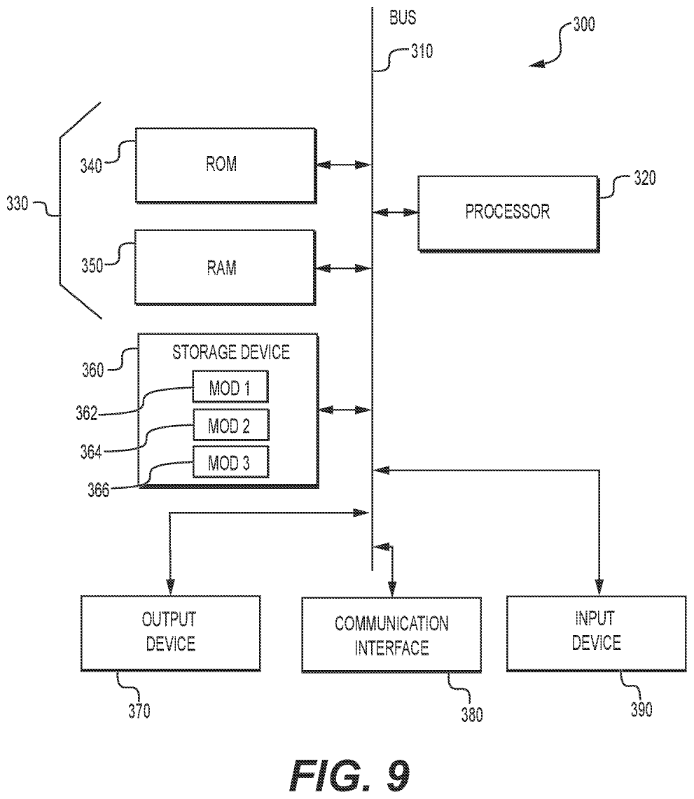

In this embodiment, the unit controller 250 is a microprocessor-based controller that includes a processor 252 for performing various functions discussed herein, and a memory 254 for storing various data. The controller 250 may also be referred to as a central processing unit (CPU) and may be the general-purpose computing device 300 shown and described below with reference to FIG. 9. In one embodiment, the various methods discussed below may be implemented by way of a series of instructions stored in the memory 254 and executed by the processor 252.

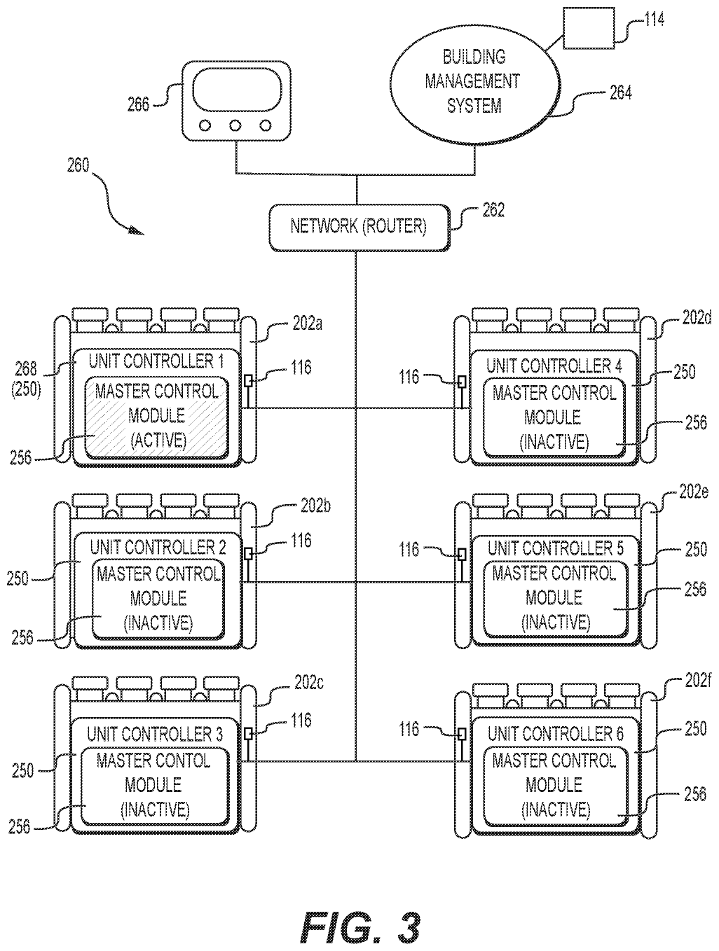

FIG. 3 is a schematic diagram of a control system 260 for the air conditioning system 200. FIG. 3 schematically depicts unit controllers 250 for six air conditioning units 202 (first air conditioning unit 202a, second air conditioning unit 202b, third air conditioning unit 202c, fourth air conditioning unit 202d, fifth air conditioning unit 202e, and sixth air conditioning unit 202f). The air conditioning units 202 and, more specifically, the unit controllers 250 of each air conditioning unit 202 are communicatively coupled to each other by a router network 262 in this embodiment. The unit controllers 250 of each air conditioning unit 202 are communicatively coupled to a building management system 264 and/or a user input device 266 by the router network 262. The input device 266 may be any suitable user input device including, for example, a control panel such as a touch screen control panel with a web interface. The building management system 264 may also be considered a user input device.

A master controller is used to operate the air conditioning system 200. Every unit controller 250 has the ability to be the master controller. In this embodiment, each unit controller 250 includes a master control module 256. The master control module 256 may be a software module that include a series of instructions stored on the memory 254 that, when executed by the processor 252, allows the unit controller 250 to operate as the master controller in addition to operating as the unit controller 250 for the respective air conditioning unit 202. As the master controller of embodiments herein is thus not a separate controller but a unit controller 250 with an active master control module 256, the master control of the system is thus referred to herein as a unit controller functioning as the master control module 268.

In FIG. 3, the unit controller 250 for the first air conditioning unit 202a is functioning as the master, and the master control module 256 of this unit controller 250 is active. The unit controllers 250 for the other air conditioning units 202b, 202c, 202d, 202e, 202f are being operated by the master control module 256 (unit controller 250 of the first air conditioning unit 202a) and are thus operating as slave units with their master control modules 256 being inactive at this time.

The unit controller functioning as the master control module 268 receives data from the building management system 264 and/or the input device 266 to determine how the air conditioning system 200 is to be operated based on customer requirements. Such data may be referred to herein as input data. For example, the unit controller functioning as the master control module 268 may receive desired setpoints from the user via the building management system 264 or the input device 266. The unit controller functioning as the master control module 268 may also receive data relative to those set points, such as desired temperature of the supply air 122, air flow of the supply air 122, temperature of the return air 124, inlet temperature to the racks 112, and/or outlet temperature from the racks 112. Sensors 114 may be used to provide such data. The sensors 114 are communicatively coupled to the unit controller functioning as the master control module 268, and in the embodiment shown in FIG. 3, the sensors 114 are indirectly coupled to the unit controller functioning as the master control module 268 through the building management system 264. Alternatively or in addition, each air conditioning unit 202 may include one or more sensors 116 coupled to the unit controller functioning as the master control module 268 thought the router network 262. Such an arrangement allows for a distributed network of sensors that further increases redundancy of the air conditioning system 200 by eliminating single point failures from a failed sensor.

In the embodiment shown in FIG. 3, all of the unit controllers 250 are communicatively connected to the building management system 264 and sensors 114, and thus a plurality of the unit controllers 250, such as all of the unit controllers 250, may be configured to receive the input data. In some embodiments, each unit controller of the plurality of the unit controllers 250 may be configured to store in its corresponding memory 254 the input data. In such an embodiment, only the unit controller functioning as the master control module 268 is acting on the data, but the other unit controllers 250 store the data in the event that the unit controller functioning as the master control module 268 fails and a new unit controller 250 is selected as the unit controller functioning as the master control module 268, as discussed further below.

The unit controller functioning as the master control module 268 uses the customer requirements, the desired setpoints, and/or other data from the sensors 114 to determine (set) operational set points for each air conditioning unit 202. The unit controller functioning as the master control module 268 may be configured to set the at least one operational set point based on input received from the building management system 264 and configured to set the at least one operational set point based on information received from the sensors 114. The unit controller functioning as the master control module 268 then provides at least one operational set point to each unit controller 250. The unit controller 250 then controls the air conditioning unit 202, such as by adjusting the operation of at least one adjustable component based on the at least one operational set point received from the unit controller functioning as the master control module 268. The unit controller functioning as the master control module 268 can provide operational set points that differ between air conditioning units 202 in order to achieve the desired conditions for the server room 110, for example. Even if the air conditioning units 202 have identical operational set points provided to them by the unit controller functioning as the master control module 268, the unit controller functioning as the master control module 268 does not directly control the adjustable component by sending commands to adjust the adjustable component internal to the air conditioning unit 202. Instead, the unit controller 250 is providing that level of control.

With the unit controller 250 operating each air conditioning unit 202, the air conditioning unit 202 can be operated based on the specific, local conditions for that air conditioning unit 202. For example, the unit controller functioning as the master control module 268 may provide identical operational set points to each unit controller 250 of the first air conditioning unit 202a and the second air conditioning unit 202b. Based on the received operational set points, the unit controller 250 of the first air conditioning unit 202a operates the first air conditioning unit 202a in the active mode, but the unit controller 250 of the second air conditioning unit 202b operates the second air conditioning unit 202b in the passive mode. Such a situation may occur, for example, where the first air conditioning unit 202a is located on the south side of the data center 100 but the second air conditioning unit 202b is located on the north side of the data center 100. During certain times of the day, the first air conditioning unit 202a may be in the sun, but the second air conditioning unit 202b is in the shade, resulting in a local ambient air temperature around the first air conditioning unit 202a that is higher than the local ambient air temperature around the second air conditioning unit 202b. Based on this ambient air temperature differences, the unit controller 250 of the first air conditioning unit 202a may operate the first air conditioning unit 202a differently than the unit controller 250 of the second air conditioning unit 202b operates the second air conditioning unit 202b.

In some embodiments, the unit controller functioning as the master control module 268 may stage the air conditioning units 202 on or off (selectively turn on or off the air conditioning units 202). For example, the unit controller functioning as the master control module 268 may operate the first air conditioning unit 202a and the second air conditioning unit 202b, but direct the third air conditioning unit 202c to be off. Using these types of controls, the unit controller functioning as the master control module 268 may rotate the air conditioning unit 202 based on hours operated, for example.

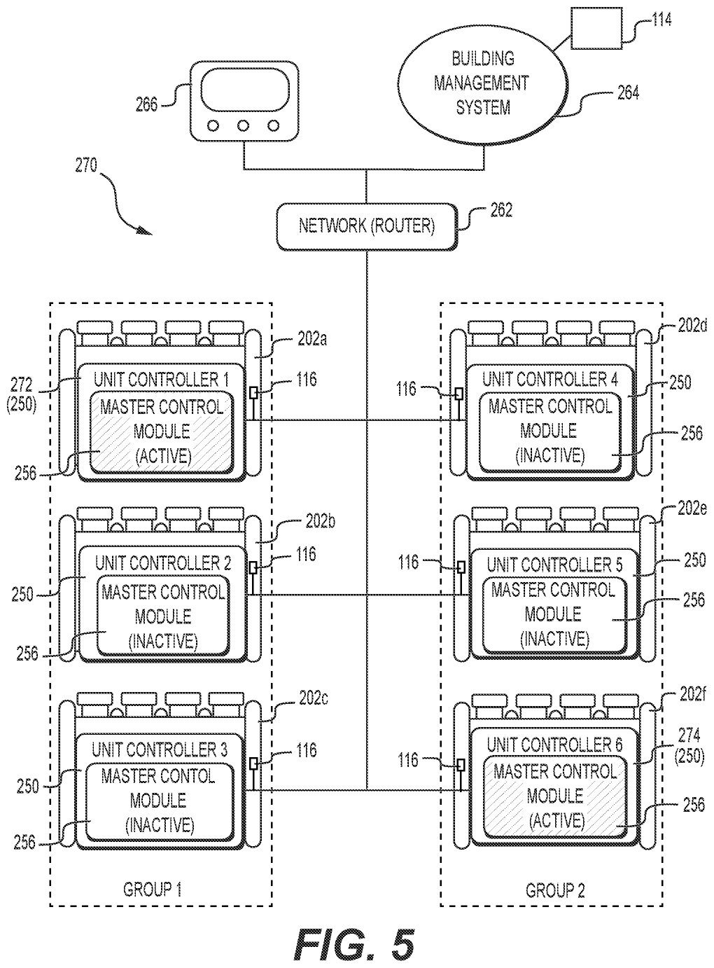

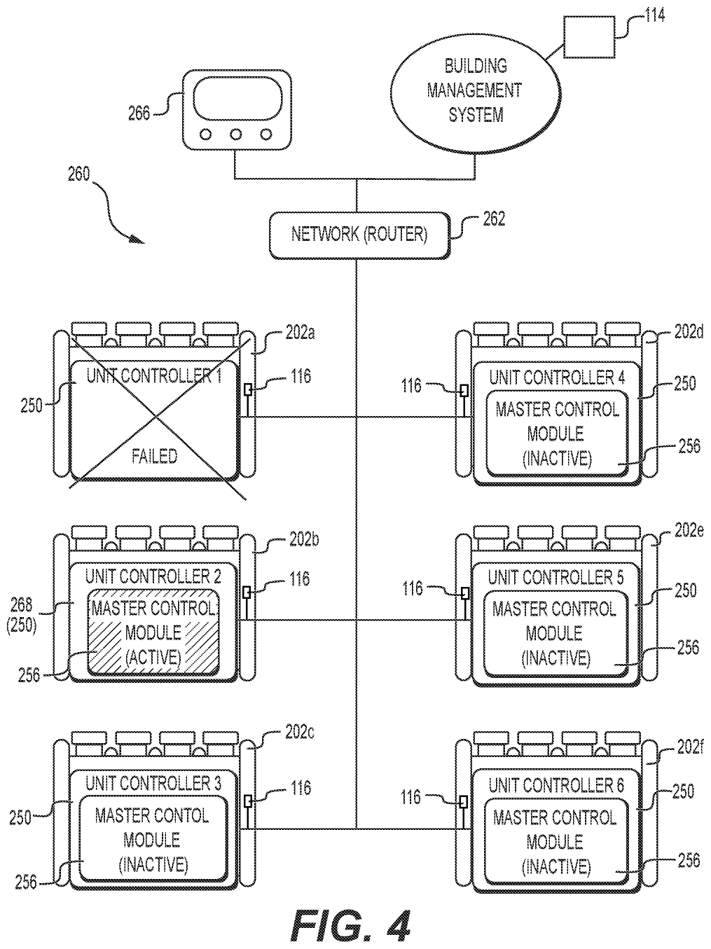

FIG. 4 is a schematic diagram of a control system 260 where the unit controller 250 for the first air conditioning unit 202a has failed and is offline. When the air conditioning system 200 is operating in the configuration shown in FIG. 3 and then the unit controller 250 for the first air conditioning unit 202a goes offline, the remaining unit controllers 250 select a new unit controller to function as the master control module from the unit controllers 250 of the plurality of air conditioning units 202. In FIG. 5, the remaining unit controllers 250 selected the unit controller 250 of the second air conditioning unit 202b to function as the master control module, and the master control module 256 of the unit controller 250 is activated. Any suitable method may be used to select the new unit controller functioning as the master control module 268. For example, each unit controller 250 may be assigned an identification number, and the operating unit controller 250 with the lowest identification number may become the unit controller functioning as the master control module 268.

The unit controller functioning as the master control module 268 may send out the operational set points periodically, regardless of whether or not the operational set points have changed. Each unit controller 250 receives the operational set point and stores the operational set point in the memory 254. One method of determining that the unit controller functioning as the master control module 268 has failed or is offline is when the unit controller 250 does not receive the operational set point when expected (e.g., has not received an operational set point over a set duration of time). However, other suitable methods may be used to determine when the unit controller functioning as the master control module 268 has failed or is otherwise offline. In one alternative method, the unit controller functioning as the master control module 268 periodically sends a signal (a heartbeat). If this heartbeat is not received by the unit controllers 250, the unit controllers 250 select a new unit controller to function as the master control module. In another alternative method, each unit controller 250 has an identification code (ID). Each unit controller 250 collects the IDs from the other unit controllers 250. When the unit controller functioning as the master control module 268 fails, the unit control 250 does not collect the unit ID from that unit controller 250, and the unit controllers 250 select a new unit controller to function as the master control module.

As noted above, the unit controller 250 may store the last operational set point received in memory 254. When a new unit controller 250 begins operating as the new master control module, the unit controller functioning as the master control module 268 may provide the most recent operational set point stored in the memory 254 as the operational set point until the new unit controller functioning as the master control module 268 can determine new operational set points.

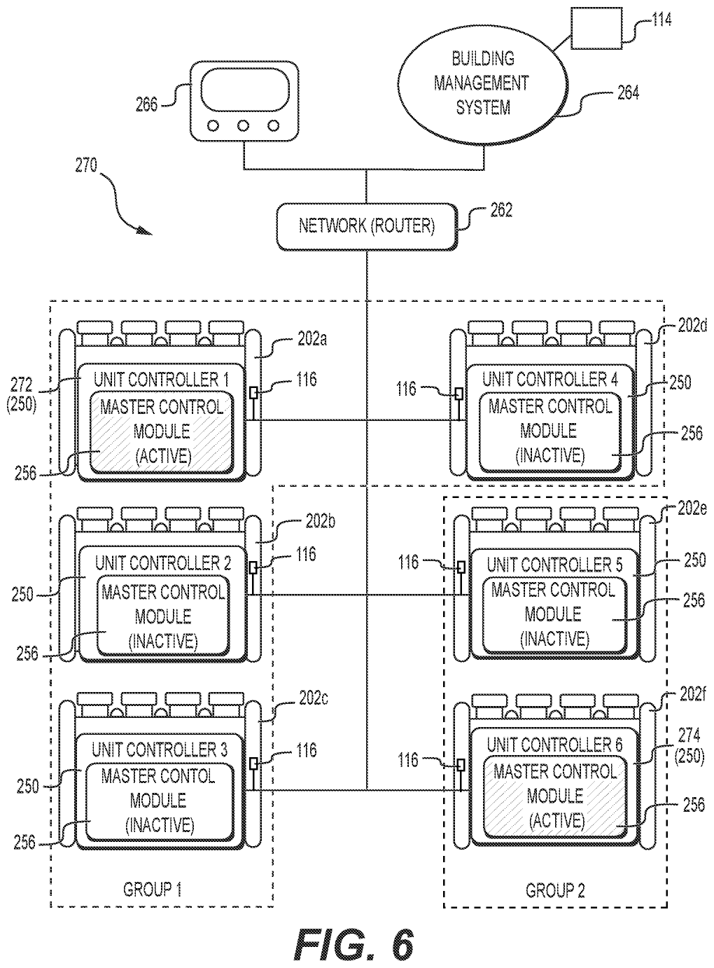

In some embodiments, the air conditioning units 202 may be operating in groups. FIGS. 5 and 6 are schematic diagrams of a control system 270 for the air conditioning system 200 where the air conditioning units 202 are organized in a plurality of groups. The control system 270 of this embodiment is similar to the control system 260 discussed above with reference to FIGS. 3 and 4. The same reference numerals will be used for components of the control system 270 of this embodiment that are the same or similar to the components of the control system 260 discussed above.

As shown in FIG. 5, the first air conditioning unit 202a, the second air conditioning unit 202b, and the third air conditioning unit 202c are operating in a first group, and the fourth air conditioning unit 202d, the fifth air conditioning unit 202e, and the sixth air conditioning unit 202f are operating in a second group. Within each group one unit controller functions as the master control module 272, 274 for each group. In FIG. 5, the unit controller 250 of the first air conditioning unit 202a is the unit controller operating as the master control module 272 for the first group, and the unit controller 250 of the sixth air conditioning unit 202f is the unit controller operating as the master control module 274 for the second group. Within the respective groups, the unit controllers 250 and the unit controller functioning as the master control module 272 for the first group or the unit controller functioning as the master control module 274 for the second group operate in the same manner as the unit controllers 250 and the unit controller operating as the master control module 268 discuss above.

The control system 270 may be configured to move air conditioning units 202 between groups. For example, the unit controller functioning as the master control module 272 for the first group may send a request to the unit controller functioning as the master control module 274 for the second group to transfer one of the air conditioning units 202 from the second group to the first group. The unit controller functioning as the master control module 274 for the second group can then accept that request and transfer one of the air conditioning units 202 to the first group. The process could also be initiated by the unit controller functioning as the master control module 274 for the second group offering to transfer one of the air conditioning units 202 from the second group to the first group and the unit controller functioning as the master control module 272 for the first group accepting that offer. As shown in FIG. 6, for example, the fourth air conditioning unit 202d has been transferred from the second group to the first group using the process outlined above.

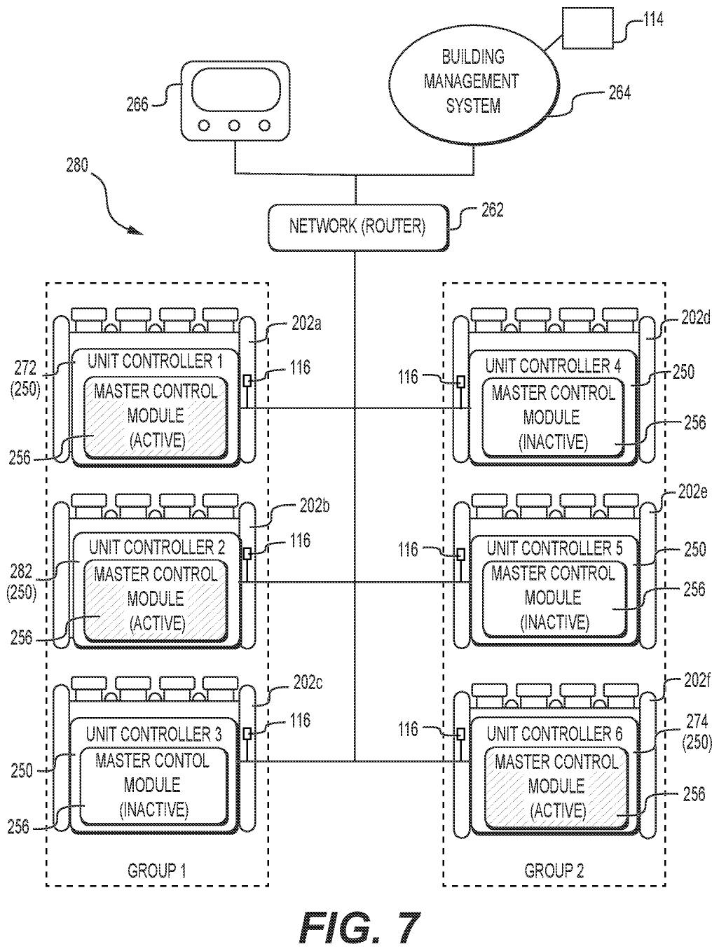

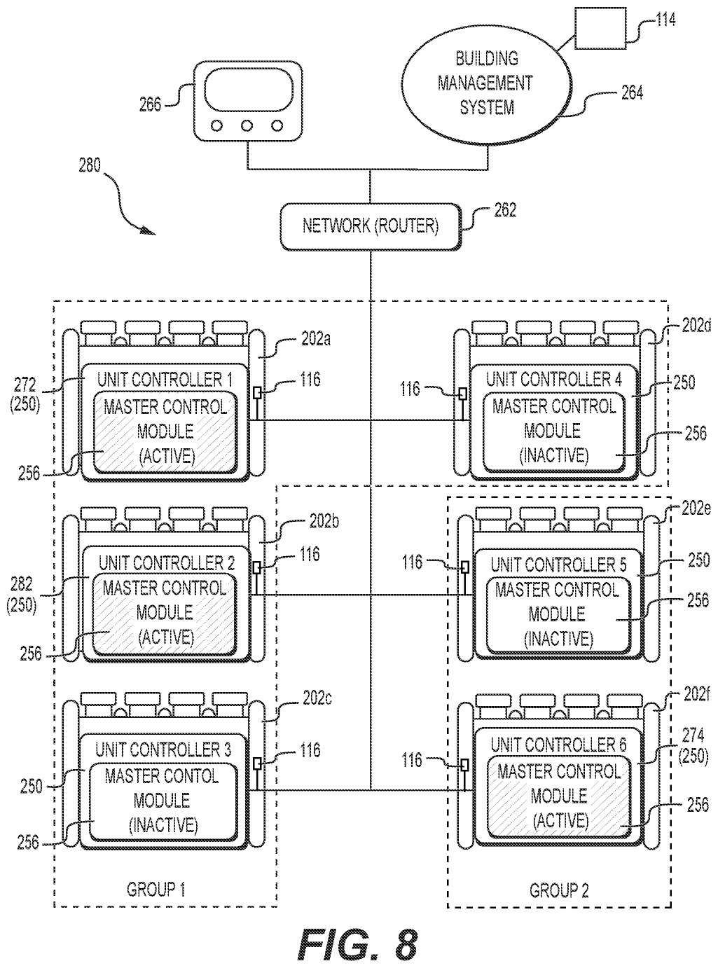

FIGS. 7 and 8 are schematic diagrams of a control system 280 for the air conditioning system 200 where the air conditioning units 202 are organized in a plurality of groups. The control system 280 of this embodiment is similar to the control system 270 discussed above with reference to FIGS. 5 and 6. The same reference numerals will be used for components of the control system 280 of this embodiment that are the same or similar to the components of the control system 270 discussed above. For embodiments where there are a plurality of groups and a plurality of unit controllers functioning as master control modules (one for each group), it may be beneficial to have system level master control. Thus, in this embodiment, one of the unit controllers functions as a master control module 282 for the system. In FIG. 7, the unit controller 250 for the second air conditioning unit 202b is functioning as the master control module 282 for the system.

The unit controller functioning as the master control module 282 for the system provides operational set points to the unit controllers functioning as master control modules for each group (e.g., the unit controller functioning as the master control module 272 for the first group and the unit controller functioning as the master control module 274 for the second group). The unit controller functioning as the master control module 282 for the system may provide the operational set points to the unit controller functioning as the master control module 272 for the first group and the unit controller functioning as the master control module 274 for the second group in a manner similar to the way the unit controller functioning as the master control module 268 provides operational set points to each unit controller 250 in the discussion above. Similarly, if the unit controller functioning as the master control module 282 for the system fails, a new unit controller may be selected as the unit controller functioning as the master control module 282 for the system in a manner similar to the unit controller functioning as the master control module 268 as discussed above.

The unit controller functioning as the master control module 282 for the system may move air conditioning units 202 between groups. In FIG. 8, the unit controller functioning as the master control module 282 for the system has moved the fourth air conditioning unit 202d from the second group to the first group.

In the embodiment shown and described in FIGS. 7 and 8, the unit controller functioning as the master control module 282 for the system is a different unit controller 250 from the master control module 272 for the first group and the unit controller functioning as the master control module 274 for the second group, but other arrangements are possible. For example, one unit controller 250 may function as both the master control module 282 for the system and the master control module for the one of the groups (e.g., one of the master control module 272 for the first group or the master control module 274 for the second group).

FIG. 9 shows a general-purpose computing device 300 (system) that may be used as the unit controller 250 discussed herein. The general-purpose computing device 300 shown in FIG. 6 includes a processing unit (CPU or processor) 320 and a system bus 310 that couples various system components including the system memory 330, such as read-only memory (ROM) 340 and random-access memory (RAM) 350, to the processor 320. The computing device 300 can include a cache of high-speed memory connected directly with, in close proximity to, or integrated as part of the processor 320. The computing device 300 copies data from the memory 330 and/or the storage device 360 to the cache for quick access by the processor 320. In this way, the cache provides a performance boost that avoids processor 320 delays while waiting for data. These and other modules can control or be configured to control the processor 320 to perform various actions. The memory 330 can include multiple different types of memory with different performance characteristics. It can be appreciated that the disclosure may operate on a computing device 300 with more than one processor 320 or on a group or cluster of computing devices networked together to provide greater processing capability. The processor 320 can include any general-purpose processor and a hardware module or software module, such as module 1 362, module 2 364, and module 3 366 stored in storage device 360, configured to control the processor 320, as well as a special-purpose processor where software instructions are incorporated into the actual processor design. The processor 320 may essentially be a completely self-contained computing system, containing multiple cores or processors, a bus, memory controller, cache, etc. A multi-core processor may be symmetric or asymmetric.

The system bus 310 may be any of several types of bus structures, including a memory bus or memory controller, a peripheral bus, and a local bus using any of a variety of bus architectures. A basic input/output (BIOS) stored in ROM 340 or the like may provide the basic routine that helps to transfer information between elements within the computing device 300, such as during start-up. The computing device 300 further includes storage devices 360 such as a hard disk drive, a magnetic disk drive, an optical disk drive, a tape drive or the like. The storage device 360 can include software modules 362, 364, 366 for controlling the processor 320. Other hardware or software modules are contemplated. The storage device 360 is connected to the system bus 310 by a drive interface. The drives and the associated computer-readable storage media provide nonvolatile storage of computer-readable instructions, data structures, program modules, and other data for the computing device 300. In one aspect, a hardware module that performs a particular function includes the software component stored in a tangible computer-readable storage medium in connection with the necessary hardware components, such as the processor 320, bus 310, output device 370, and so forth, to carry out the function. In another aspect, the system can use a processor and computer-readable storage medium to store instructions which, when executed by a processor (e.g., one or more processors), cause the processor to perform a method or other specific actions. The basic components and appropriate variations are contemplated depending on the type of device, such as whether the computing device 300 is a small, handheld computing device, a desktop computer, or a computer server.

Although the exemplary embodiment described herein employs a hard disk as the storage device 360, other types of computer-readable media which can store data that are accessible by a computer, such as magnetic cassettes, flash memory cards, digital versatile disks, cartridges, random access memories (RAMs) 350, and read-only memories (ROMs) 340, may also be used in the exemplary operating environment. Tangible computer-readable storage media, computer-readable storage devices, or computer-readable memory devices expressly exclude media such as transitory waves, energy, carrier signals, electromagnetic waves, and signals per se.

To enable user interaction with the computing device 300, an input device 390 represents any number of input mechanisms, such as a microphone for speech, a touch-sensitive screen for gesture or graphical input, a keyboard, a mouse, and so forth. An output device 370 can also be one or more of a number of output devices known to those of skill in the art. In some instances, multimodal systems enable a user to provide multiple types of input to communicate with the computing device 300. The communications interface 380 generally governs and manages the user input and system output. There is no restriction on operating on any particular hardware arrangement, and therefore the basic features here may easily be substituted for improved hardware or firmware arrangements as they are developed.

The technology discussed herein refers to computer-based systems and actions taken by, and information sent to and from, computer-based systems. One of ordinary skill in the art will recognize that the inherent flexibility of computer-based systems allows for a great variety of possible configurations, combinations, and divisions of tasks and functionality between and among components. For instance, processes discussed herein can be implemented using a single computing device or multiple computing devices working in combination. Databases, memory, instructions, and applications can be implemented on a single system or distributed across multiple systems. Distributed components can operate sequentially or in parallel.

Although this invention has been described with respect to certain specific exemplary embodiments, many additional modifications and variations will be apparent to those skilled in the art in light of this disclosure. It is, therefore, to be understood that this invention may be practiced otherwise than as specifically described. Thus, the exemplary embodiments of the invention should be considered in all respects to be illustrative and not restrictive, and the scope of the invention to be determined by any claims supportable by this application and the equivalents thereof, rather than by the foregoing description.

What is claimed is:

1. A fluid conditioning system for conditioning a fluid, the fluid conditioning system comprising:
a plurality of fluid conditioning units, each unit of the plurality of fluid conditioning units being configured to condition a fluid, each fluid conditioning unit of the plurality of fluid conditioning units including a unit controller configured to operate the fluid conditioning unit, the unit controllers of the plurality of fluid conditioning units being communicatively coupled to each other,
wherein one unit controller of the plurality of the unit controllers functions as a master control module, the master control module providing at least one operational set point to each of the unit controllers.

2. The fluid conditioning system of claim 1, wherein, when the unit controller functioning as the master control module goes offline, the remaining unit controllers select a new unit controller to function as the master control module from the unit controllers of the plurality of fluid conditioning units.

3. The fluid conditioning system of claim 1, wherein the master control module is configured to periodically provide the at least one operational set point to each of the unit controllers, and
wherein each of the unit controllers includes a memory and is configured to store the at least one operational set point received by unit controller from the master control module in the memory.

4. The fluid conditioning system of claim 3, wherein, when at least one unit controller does not receive the at least one operational set point, the remaining unit controllers select a new unit controller to function as the master control module from the unit controllers of the plurality of fluid conditioning units.

5. The fluid conditioning system of claim 4, wherein the new master control module provides the most recent at least one operational set point stored in the memory as the at least one operational set point.

6. The fluid conditioning system of claim 1, wherein the master control module is configured to selectively turn on or off the fluid conditioning units of the plurality of fluid conditioning units.

7. The fluid conditioning system of claim 1, wherein the master control module is communicatively coupled to a user input device and configured to set the at least one operational set point based on input received from the user input device.

8. The fluid conditioning system of claim 1, wherein the master control module is communicatively coupled to a building management system and configured to set the at least one operational set point based on input received from the building management system.

9. The fluid conditioning system of claim 1, wherein the master control module is communicatively coupled to at least one sensor and configured to set the at least one operational set point based on information received from the sensor.

10. The fluid conditioning system of claim 1, wherein each fluid conditioning unit of the plurality of fluid conditioning units includes at least one adjustable component, the unit controller of the fluid conditioning unit being operatively coupled to the at least one adjustable component to adjust the operation of the at least one adjustable component based on the at least one operational set point received from the master control module.

11. The fluid conditioning system of claim 10, wherein the adjustable component is one of a fan, a compressor, a pump, a valve, a damper, an electric heater, an actuator, a motor, a switch, and a relay.

12. The fluid conditioning system of claim 1, wherein the plurality of fluid conditioning units is a first group of fluid conditioning units and the unit controller functioning as the master control module is a master control module for the first group,
wherein the fluid conditioning system further comprises:
a plurality of fluid conditioning units in a second group, each unit of the plurality of fluid conditioning units in the second group being configured to condition a fluid, each fluid conditioning unit of the plurality of fluid conditioning units in the second group including a unit controller configured to operate the fluid conditioning unit, the unit controllers of the plurality of fluid conditioning units of the second group being communicatively coupled to each other, wherein one unit controller of the plurality of the unit controllers of the second group functions as a master control module for the second group, the master control module providing at least one operational set point to each of the unit controllers of the second group.

13. The fluid conditioning system of claim 12, wherein one unit controller of the plurality of the unit controllers of either the first group or the second group functions as a master control module for the fluid conditioning system.

14. The fluid conditioning system of claim 13, wherein the master control module for the fluid conditioning system is configured to change a fluid conditioning unit from the first group of the plurality of fluid conditioning units to the second group of the plurality of fluid conditioning units.

15. The fluid conditioning system of claim 1, wherein the fluid is air and the plurality of fluid conditioning units is a plurality of air conditioning units, each of the air conditioning units being fluidly coupled to a space and configured to provide conditioned air to the space.

16. A controller for a fluid conditioning unit, the controller comprising:
a processor; and
a computer-readable storage medium storing instructions, which, when executed by the processor, cause the controller:
(i) to operate as a unit controller controlling the fluid conditioning unit based on at least one operational set point; and
(ii) to operate as a master controller, the controller being selectively operable as the master controller, and, when operating as the master controller, the instructions causing the controller to output the at least one operational set point.

17. The controller of claim 16, wherein the computer-readable storage medium further stores instructions to receive the at least one operational set point.

18. The controller of claim 17, wherein, when the controller does not receive the at least one operational set point, the computer-readable storage medium further stores instructions to execute the instructions that cause the controller to operate as a master controller.

19. A method of conditioning a fluid using a fluid conditioning system including a plurality of fluid conditioning units, each fluid conditioning unit of the plurality of fluid conditioning units including a unit controller configured to operate the fluid conditioning unit, the method comprising:
determining when a unit controller operating as a master control module for the fluid conditioning system goes offline, the unit controller functioning as the master control module being communicatively coupled to each of the unit controllers to provide at least one operational set point to each of the unit controllers; and
selecting a new unit controller to function as the master control module from the unit controllers of the plurality of fluid conditioning units.

20. The method of claim 19, wherein the master control module is configured to periodically provide the at least one operational set point to each of the unit controllers, and the unit controller functioning as the master control module is determined to be offline when at least one unit controller does not receive the at least one operational set point.
